(19) United States
(12) Patent Application Publication
(10) Pub. No.: US 2017/0084519 A1
(43) Pub. Date: Mar. 23, 2017

(54) SEMICONDUCTOR PACKAGE AND METHOD OF MANUFACTURING SAME

(71) Applicant: FREESCALE SEMICONDUCTOR, INC., AUSTIN, TX (US)

(72) Inventors: THOMAS C. SPEIGHT, Chandler, AZ (US); Stephen R. Hooper, Mesa, AZ (US)

(21) Appl. No.: 14/861,543

(22) Filed: Sep. 22, 2015

(51) Int. Cl. H01L 23/495; H01L 21/78; H01L 21/56; H01L 23/31

(52) U.S. Cl. CPC H01L 23/49541; H01L 23/3107; H01L 21/78; H01L 21/56

(57) ABSTRACT

A semiconductor die is electrically connected to the leads of a flagless lead frame and is fully encapsulated by encapsulant to form a semiconductor package. A method of manufacturing the semiconductor package entails encapsulating a flagless lead frame with a first encapsulant such that a top surface of the leads of the flagless lead frame are exposed from the first encapsulant. A semiconductor die is mounted directly to the first encapsulant located in a central region of the lead frame. Electrically conductive interconnects are formed between die pads on the semiconductor die and the top surface of respective leads of the lead frame. The semiconductor die, conductive interconnects, and top surface of the leads is encapsulated with a second encapsulant so that the semiconductor die is sandwiched between the first and second encapsulants, thus isolating the semiconductor die from package stresses.

### TECHNICAL FIELD OF THE INVENTION

The present invention relates generally to methods for manufacturing semiconductor packages. More specifically, the present invention relates to manufacturing semiconductor packages with reduced package stress.

### BACKGROUND OF THE INVENTION

Semiconductor packages are incorporated into most conventional electronic devices such as, for example, laptop computers, mobile telephones, games, medical devices, vehicles, and so forth. These semiconductor packages are typically formed from a metal lead frame that usually includes an arrangement of external connection leads and a flag (also referred to as a die pad) to which is mounted a semiconductor die. Electrical connection pads of the semiconductor die are electrically connected to the leads of the lead frame with wires. The semiconductor die and wires are then encapsulated, typically by a molding compound, to form the final semiconductor package.

Many semiconductor packages are sensitive to temperature stresses due to mismatched Coefficients of Thermal Expansion (CTE) of the various materials used inside the semiconductor package, as well as due to coupling of the semiconductor package to a system printed circuit board (PCB). The CTE describes how the size of an object changes with a change in the temperature. The mismatch of CTE's of the materials within a semiconductor package, as well as to the PCB substrate, can result in damage to the semiconductor package (such as cracking, delamination, solder fatigue, package and die warpage, and the like) under thermal shock or thermal cycling conditions. These problems can occur at the time of joining the semiconductor package to the PCB substrate or subsequently during the operating life of the semiconductor package. Accordingly, there remains a need for improved packaging of semiconductor dies to reduce or minimize the adverse effects of CTE mismatch in semiconductor packages.

### BRIEF DESCRIPTION OF THE DRAWINGS

The accompanying figures in which like reference numerals refer to identical or functionally similar elements throughout the separate views, the figures are not necessarily drawn to scale, and which together with the detailed description below are incorporated in and form part of the specification, serve to further illustrate various embodiments and to explain various principles and advantages all in accordance with the present invention.

FIG. 1 shows a cross-sectional side view of a semiconductor package in accordance with an example embodiment;

FIG. 2 shows a plan view of a lead frame formed from an electrically conductive sheet;

FIG. 3 shows a plan view of a conductive sheet that includes a plurality of lead frames;

FIG. 4 shows a flow chart of a semiconductor package manufacturing process in accordance with another example embodiment;

FIG. 5 shows a plan view of a portion of a molded structure formed in accordance with the semiconductor package manufacturing process of FIG. 4;

FIG. 6 shows a cross-sectional side view of the molded structure along section lines 6-6 of FIG. 5;

FIG. 7 shows a plan view of the molded structure of FIG. 5 with semiconductor dies mounted to it in accordance with the semiconductor package manufacturing process of FIG. 4;

FIG. 8 shows a cross-sectional side view of a composite structure formed in accordance with the semiconductor package manufacturing process of FIG. 4;

FIG. 9 shows a flow chart of a semiconductor package manufacturing process in accordance with another example embodiment;

FIG. 10 shows a cross-sectional side view of a structure formed in accordance with the semiconductor manufacturing process of FIG. 9;

FIG. 11 shows a cross-sectional side view of the structure of FIG. 10 following encapsulation in accordance with the semiconductor manufacturing process of FIG. 9; and;

FIG. 12 shows a cross-sectional side view of the structure of FIG. 11 following bottom side etching in accordance with the semiconductor manufacturing process of FIG. 9.

### DETAILED DESCRIPTION

In overview, the present disclosure concerns semiconductor packages and methods of their manufacture. The semiconductor packages described herein each include at least one semiconductor die that is fully surrounded by an encapsulant, i.e., a mold compound. Methodology entails encapsulating a flagless lead frame in a first encapsulant to form a molded structure, mounting the semiconductor die or dies directly to the first encapsulant, forming electrically conductive interconnects between die pads on the semiconductor die and the leads of the lead frame, then encapsulating the semiconductor die, the interconnects, and the leads in a second encapsulant. The various inventive concepts and principles embodied in the methods and semiconductor packages may reduce or minimize the adverse affects of CTE mismatch in semiconductor packages for improved manufacturing yield, improved reliability, and cost savings.

The instant disclosure is provided to further explain in an enabling fashion the best modes, at the time of the application, of making and using various embodiments in accordance with the present invention. The disclosure is further offered to enhance an understanding and appreciation for the inventive principles and advantages thereof, rather than to limit in any manner the invention. The invention is defined solely by the appended claims including any amendments made during the pendency of this application and all equivalents of those claims as issued.

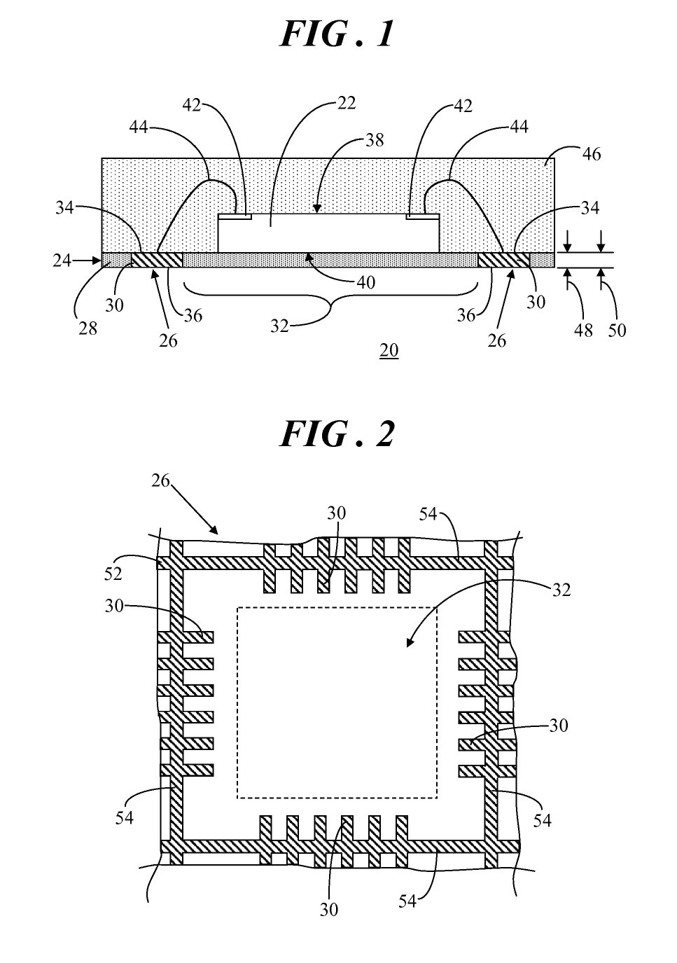

Referring to FIG. 1, FIG. 1 shows a cross-sectional side view of a semiconductor package 20 in accordance with an example embodiment. Semiconductor package generally includes a semiconductor die 22 mounted to a molded structure 24. Semiconductor die 22 is represented by a single rectangular box for simplicity of illustration. It should be understood, however, that semiconductor package 20 may include multiple semiconductor dies that are laterally displaced from one another or that are in a stacked configuration.

In a particular embodiment, molded structure 24 includes a lead frame 26 embedded in a first encapsulant 28. Lead frame 26 includes a plurality of external connection leads 30 (two shown in FIG. 1) extending toward a central region 32 of lead frame 26. A top surface 34 and a bottom surface 36 of leads 28 are exposed from first encapsulant 28. It should be understood that the use of relational terms, if any, such as first and second, top and bottom, and the like are used solely to distinguish one from another entity or action without necessarily requiring or implying any actual such relationship or order between such entities or actions.

Semiconductor die 22 includes a first surface, referred to herein as a connection pad surface 38, and a second surface, referred to herein as a mounting surface 40. Mounting surface 40 of semiconductor die 22 is mounted to encapsulant 28 in central region 32 of lead frame 26. The central region of a conventional lead frame typically includes a flag (also called a die pad) upon which a semiconductor die, multiple dies, or a die stack is mounted. In an embodiment, lead frame 26 does not include a flag at central region 32. Hence, lead frame 26 is “flagless” so that mounting surface 40 of semiconductor die 22 can be coupled directly to first encapsulant 28.

Connection pad surface 38 has die pads 42 formed thereon. Electrically conductive interconnects 44, such as bond wires, are connected between die pads 42 and top surface 34 of respective ones of leads 30 of lead frame 26. Leads 30 are laterally displaced from semiconductor die 22 and may surround one or more sides of semiconductor die 22. Semiconductor die 22, conductive interconnects 36, and top surface 34 of leads 30 are covered, i.e., encapsulated, by, a second encapsulant 46.

Lead frame 26 exhibits a first height 48 and molded structure 24 has a second height 50 that is approximately equivalent to first height 48. Accordingly, it should be readily observed that when semiconductor die 22 is mounted to first encapsulant 28 in central region 32, mounting surface 40 of semiconductor die 22 is approximately coplanar with top surface 34 of leads 28. That is, mounting surface 40 of semiconductor die 22 is vertically displaced away from an external surface of semiconductor package 20 so that semiconductor die 22 is sandwiched between first encapsulant 28 and second encapsulant 46.

In FIG. 1, first encapsulant 28 is represented by a heavily stippled pattern and second encapsulant 46 is represented by a lightly stippled pattern in order to distinguish them from one another. However, first encapsulant 28 and second encapsulant 46 may each be formed from the same material, e.g., a mold compound or a protective resin. However, as will be discussed in detail below, separate encapsulating operations are provided to initially encapsulate lead frame 26 with first encapsulant 28, followed by encapsulating semiconductor die 22, conductive interconnects 36, and top surface 34 of leads 30 with second encapsulant 46.

First and second encapsulants 28, 46 protect semiconductor die 22 from exposure to external elements, e.g., air, moisture, liquids, and/or the substance of interest. Thus, first and second encapsulants 28, 46 provide robust mechanical and environmental protection. Furthermore, first and second encapsulants 28, 46 fully surround semiconductor die 22 thereby isolating semiconductor die 22 in order to effectively reduce package induced stresses on semiconductor die 22. First and second encapsulants 28, 46 may be formed in any suitable manner, as will be discussed in greater detail below, and any suitable molding material (e.g., epoxy- or silicone-based compounds) may be used.

FIG. 2 shows a plan view of lead frame 26 integrally formed from an electrically conductive sheet 52 (typically a copper sheet). As shown, leads 30 of lead frame 26 extend inwardly from a lead frame boundary, formed by tie-bars 54, toward central region 32. Since lead frame 26 is flagless, central region 32 is generally indicated by a rectangular area outlined in phantom. As previously mentioned, lead frame 26 is integrally formed from electrically conductive sheet 52. Additionally, there are other identical lead frames 26 also formed from conductive sheet 52. Therefore, as illustrated, the other identical lead frames 26 share tie-bars 54 of lead frame 26.

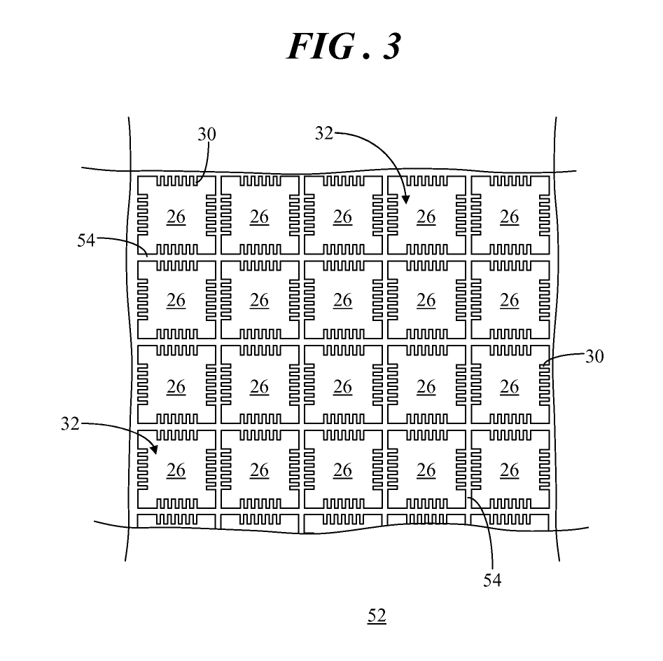

FIG. 3 shows a plan view of electrically conductive sheet 52 that includes a plurality of lead frames 26 integrally formed in sheet 52. As shown, lead frames 26 are interconnected by tie-bars 54. Additionally, each of leads frames 26 includes its respective leads 30 inwardly extending to its respective central region 32.

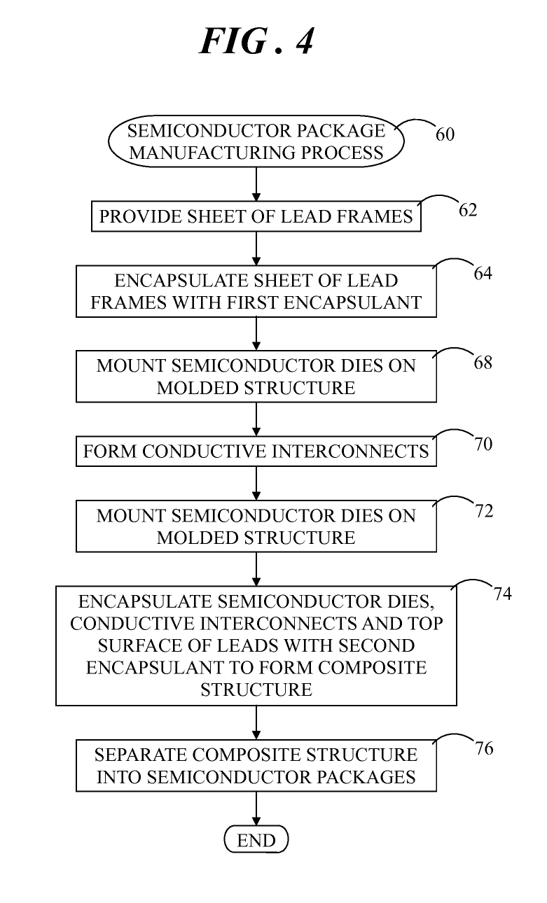

FIG. 4 shows a flow chart of a semiconductor package manufacturing process 60 in accordance with another example embodiment. Semiconductor package manufacturing process 60 may be implemented in a high volume manufacturing environment to cost effectively produce mechanically robust semiconductor packages that are fully surrounded by encapsulant in order to effectively reduce package induced stresses on semiconductor die 22. In this example, process 60 is described in connection with manufacturing a plurality of semiconductor packages 20 utilizing conductive sheet 52. Thus, reference should be made to FIGS. 1-4 concurrently with the following description.

At a block 62 of semiconductor package manufacturing process 60, conductive sheet 52 of lead frames 26 is provided. Conductive sheet 52 may be fabricated by the manufacturing facility that is executing process 60. Alternatively, conductive sheet 52 may be fabricated by an outside manufacturing facility and is thus provided by that outside manufacturing facility.

At a block 64, conductive sheet 52 that includes the plurality of flagless lead frames 26 is encapsulated with first encapsulant 28, which may be, for example, a mold compound or protective resin. Encapsulation block 64 can entail taping the bottom of conductive sheet 52 and then encapsulating conductive sheet 52. When conductive sheet 52 is encapsulated with first encapsulant 28, the tape will prevent first encapsulant 28 from bleeding out onto bottom surfaces 36 of leads 30. Additionally, conductive sheet 52 will be molded to the same height as lead frames 26 so that top surfaces of leads 30 are not covered with first encapsulant 28. As such, top surfaces 34 and bottom surfaces 36 of leads 30 are exposed from first encapsulant 28 following encapsulation. Thus, molded structure 24 is formed.

At a block 68, semiconductor dies 22 are mounted on first encapsulant 28 located in each central region 32 of each lead frame 26 formed in conductive sheet 52. Semiconductor dies 22 may be adhered, glued, or otherwise fixed to first encapsulant 28 located in each central region 32 using, for example, a die attach film, wafer backside coating, dispensed epoxy die attach, and so forth.

At a block 70, electrically conductive interconnects 44 (e.g., bond wires) are formed between die pads 42 of semiconductor dies 22 and top surfaces 34 of respective ones of leads 30. At a block 72, semiconductor dies 22, conductive interconnects 44, and top surfaces 34 of leads 30 are encapsulated in second encapsulant 46, which may be, for example, a mold compound or protective resin, to form a composite structure. Thereafter, at a block 74, the composite structure is separated into individual semiconductor packages 20 and process 60 ends.

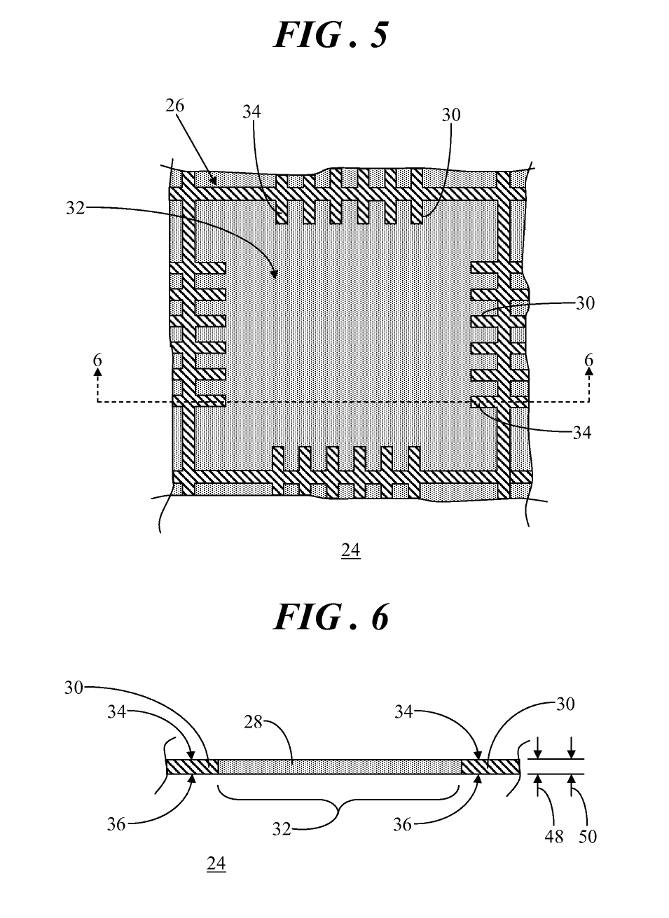

Now referring to FIGS. 5 and 6, FIG. 5 shows a plan view of a portion of molded structure 24 formed in accordance with semiconductor package manufacturing process 60 (FIG. 4), and FIG. 6 shows a cross-sectional side view of molded structure 24 along section lines 6-6 of FIG. 5. FIGS. 5 and 6 show only one of lead frames 26 embedded in first encapsulant 28 for simplicity of illustration. However, it should be understood that the methodology of FIG. 4 results in the plurality of integral lead frames 26 of conductive sheet 52 will all be embedded in first encapsulant 28 and thus make up molded structure 24.

As revealed in FIGS. 5 and 6, first encapsulant 28 fills the entire volume of central region 32 that is absent a flag, or die pad. Additionally, first encapsulant 28 fills the volume between adjacent leads 24. Further, top surfaces 34 and bottom surfaces 36 of leads 30 are exposed from first encapsulant 28. Thus, second height 50 of first encapsulant 28 is generally equivalent to first height 48 of leads 30.

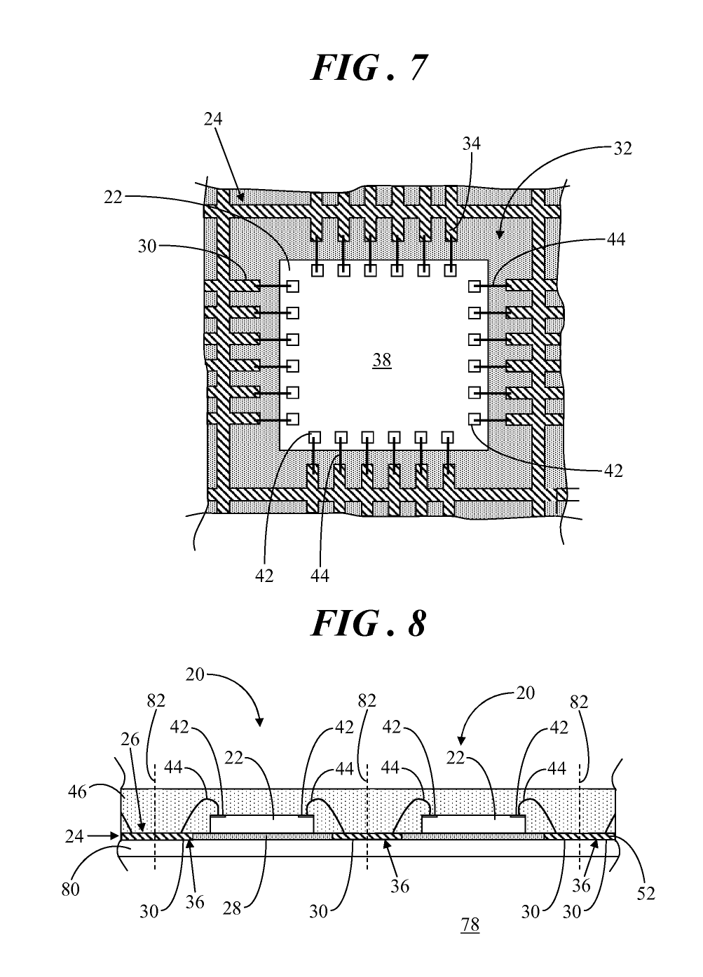

FIG. 7 shows a plan view of the portion of molded structure 24 of FIG. 5 with semiconductor dies 22 mounted to it in accordance with semiconductor package manufacturing process 60 (FIG. 4). As shown in FIG. 7, semiconductor die 22 is adhered, glued, or otherwise directly coupled to first encapsulant 28 in central region 32 with connection pad surface 38 facing upwardly in the illustration. Thus, die pads 42 at connection pad surface 38 are exposed. Additionally, electrically conductive interconnects 44 have been formed between die pads 42 and top surfaces 34 of leads 30.

FIG. 8 shows a cross-sectional side view of a composite structure 78 formed in accordance with semiconductor package manufacturing process 60 (FIG. 4). Composite structure 78 includes molded structure 24 having conductive sheet 52 of lead frames 26 embedded in first encapsulant 28. Composite structure 78 additionally includes semiconductor dies 22 mounted to first encapsulant 28, as discussed above, and interconnects 44, all of which is encapsulated or covered by second encapsulant 46. As shown, composite structure 78 is placed on a temporary carrier 80 with the exposed bottom surfaces 36 of leads 30 facing temporary carrier 80. Thereafter, composite structure 78 undergoes a singulation process along dicing lines 82 to separate composite structure 78 into a plurality of semiconductor packages 20.

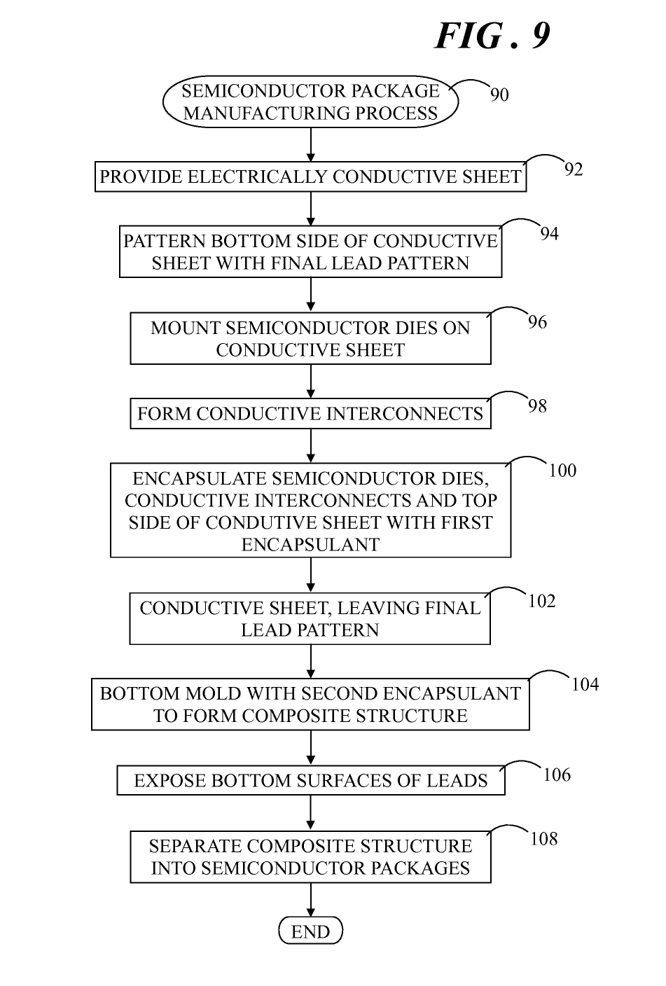

Referring now to FIG. 9, FIG. 9 shows a flow chart of a semiconductor package manufacturing process 90 in accordance with another example embodiment. Semiconductor package manufacturing process 90 may be implemented in a high volume manufacturing environment to cost effectively produce mechanically robust semiconductor packages that are fully surrounded by encapsulant in order to effectively reduce package induced stresses on semiconductor die 22. In this alternative example, process 90 is also described in connection with manufacturing a plurality of semiconductor packages 20.

At a block 92 of semiconductor package manufacturing process 60, an electrically conductive sheet is provided. However, unlike conductive sheet 52, described above, the conductive sheet at block 92 may simply be a sheet (e.g., copper) that has not yet been patterned or shaped to include leads. At a block 94, the bottom side of the conductive sheet is patterned with a final lead pattern. That is, the conductive sheet is suitably masked at those locations where leads that will be used for external connections will be formed in subsequent processing operations. The remainder of the conductive sheet is not covered by the mask material.

At a block 96, semiconductor dies 22 are mounted on the conductive sheet at suitable locations. Semiconductor dies 22 may be adhered, glued, or otherwise fixed to the flags using, for example, a die attach film, wafer backside coating, dispensed epoxy die attach, and so forth. At a block 98, electrically conductive interconnects 44 (e.g., bond wires) are formed between die pads 42 of semiconductor dies 22 and top surfaces of respective ones of the leads that will eventually be formed in the conductive sheet.

At a block 100, semiconductor dies 22, conductive interconnects 44, and the top surface of the conductive sheet are encapsulated in first encapsulant, which may be, for example, a mold compound or protective resin. Next at a block 102, the conductive sheet is etched leaving the final pattern of leads which was suitably masked at block 94.

At a block 104, the structure is molded in a bottom molding process with a second encapsulant to embed or otherwise encapsulate the remaining leads. Thus, following execution of block 104, semiconductor dies 22 are sandwiched between first and second encapsulants. At a block 106, the bottom surfaces of the remaining leads may be exposed from the second encapsulant (if needed) and from the mask material. Thereafter, at a block 108, the composite structure is separated into individual semiconductor packages 20 and process 90 ends.

Referring now to FIG. 10, FIG. 10 shows a cross-sectional side view of a structure formed in accordance with semiconductor manufacturing process 90 (FIG. 9). The subsequent description and illustrations are described in connection with the manufacture of a single semiconductor package 20 for simplicity. It should be understood, however, that following description may be readily adapted to concurrently produce multiple semiconductor packages similar to the methodology described above.

As shown in FIG. 10, semiconductor die 22 is adhered, glued, or otherwise mounted to an electrically conductive sheet 110 with connection pad surface 38 facing upwardly in the illustration. Thus, die pads 42 at connection pad surface 38 are exposed. Semiconductor die 22 is mounted to sheet 110 at a central region 112 defined by a surrounding final lead pattern 114, where final lead pattern 114 is distinguished by regions of mask material 116 on a bottom side 118 of conductive sheet 110. Additionally, electrically conductive interconnects 44 have been formed between die pads 42 and a top side 120 of conductive sheet 110 where leads 30 will eventually be formed.

FIG. 11 shows a cross-sectional side view of the structure of FIG. 10 following encapsulation in accordance with semiconductor manufacturing process 90 (FIG. 9). That is, semiconductor die 22, conductive interconnects 44, and top side 120 of conductive sheet 110 are encapsulated or covered by encapsulant 46, which becomes a “first encapsulant” in accordance with the order of operations described in connection with semiconductor manufacturing process 90.

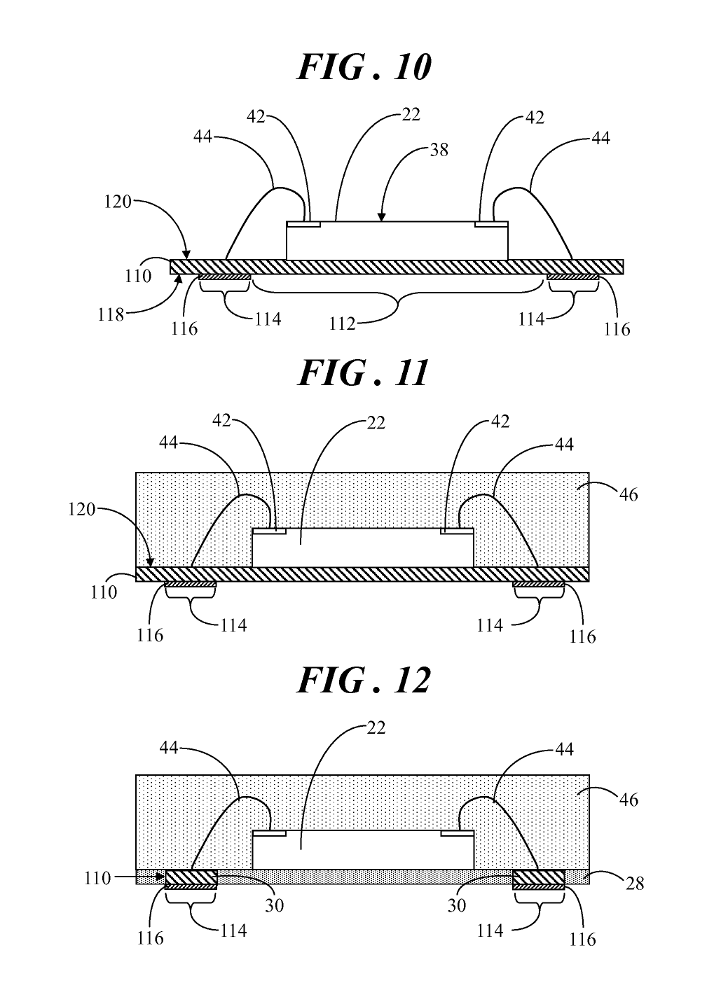

FIG. 12 shows a cross-sectional side view of the structure of FIG. 11 following bottom side etching and encapsulation in accordance with semiconductor manufacturing process 90 (FIG. 9). Following etching of conductive sheet 110, final lead pattern 114 of leads 30 remain as shown in FIG. 12. Thereafter, the bottom mold operation can be performed with a second encapsulant to form a composite structure. Thus, in accordance with the order of operations described in connection with semiconductor manufacturing process 90, encapsulant 28 becomes a “second encapsulant.” Following the second molding process, mask material 116 can be removed from leads 30 and the composite structure can be singulated into a plurality of semiconductor packages 20. Accordingly, execution of either of semiconductor manufacturing processes 60 (FIG. 4) or 90 (FIG. 9) produces the same structure, e.g., semiconductor package 20 (FIG. 1).s

Embodiments described herein entail semiconductor packages and methods of their manufacture. An embodiment of a method for manufacturing a semiconductor package comprises providing a lead frame, the lead frame being formed from an electrically conductive sheet having a plurality of leads extending from a lead frame boundary towards a central region of the lead frame, and encapsulating the lead frame with a first encapsulant such that a top surface of each of the leads is exposed from the first encapsulant. The method further comprises mounting a semiconductor die on the first encapsulant located in the central region of the lead frame, forming electrically conductive interconnects between die pads on the semiconductor die and the top surface of respective ones of the plurality of leads, and encapsulating the semiconductor die, the conductive interconnects, and the top surface of the leads with a second encapsulant.

An embodiment of a method for manufacturing a plurality of semiconductor packages comprises providing an electrically conductive sheet of flagless lead frames, each of the flagless lead frames having a plurality of leads extending from a lead frame boundary towards a central region of the lead frame, and encapsulating the electrically conductive sheet of flagless lead frames with a first encapsulant such that a top surface of each of the leads is exposed from the first encapsulant. The method further comprises mounting semiconductor dies on the first encapsulant located in each the central region of each of the flagless lead frames by directly coupling the semiconductor dies to the first encapsulant, forming electrically conductive interconnects between die pads on the semiconductor dies and the top surface of respective ones of the plurality of leads, encapsulating the semiconductor dies, the conductive interconnects, and the top surface of the leads with a second encapsulant to form a composite structure, and separating the composite structure into the plurality of semiconductor packages following both of the encapsulating operations, each of the semiconductor dies being sandwiched between a portion of the first encapsulant and a portion of the second encapsulant.

An embodiment of a semiconductor package comprises a lead frame embedded in a first encapsulant, the lead frame being formed from an electrically conductive sheet having a plurality of leads extending from a lead frame boundary towards a central region of the lead frame, wherein a top surface of each of the leads is exposed from the first encapsulant. The semiconductor package further comprises a semiconductor die in direct contact with the first encapsulant located in the central region of the lead frame, conductive interconnects electrically connected between die pads on the semiconductor die and the top surface of respective ones of the plurality of leads, and a second encapsulant covering the semiconductor die, the conductive interconnects, and the top surface of the leads.

The semiconductor packages described herein each include at least one semiconductor die that is fully surrounded by an encapsulant, i.e., a mold compound. A flagless lead frame is embedded in an encapsulant, semiconductor dies are coupled with the encapsulant, electrically conductive interconnects are formed between die pads on the semiconductor die and the leads of the lead frame, and the semiconductor die, the interconnects, and the leads in a second encapsulant. Thus, the semiconductor die is sandwiched between and fully surrounded by encapsulant to provide isolation for the semiconductor die from package stresses. The various inventive concepts and principles embodied in the methods and semiconductor packages may reduce or minimize the adverse affects of CTE mismatch in semiconductor packages for improved manufacturing yield, improved reliability, and cost savings.

This disclosure is intended to explain how to fashion and use various embodiments in accordance with the invention rather than to limit the true, intended, and fair scope and spirit thereof The foregoing description is not intended to be exhaustive or to limit the invention to the precise form disclosed. Modifications or variations are possible in light of the above teachings. The embodiment(s) was chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims, as may be amended during the pendency of this application for patent, and all equivalents thereof, when interpreted in accordance with the breadth to which they are fairly, legally, and equitably entitled.

What is claimed is:

1. A method for manufacturing a semiconductor package comprising:
providing a lead frame, said lead frame being formed from an electrically conductive sheet having a plurality of leads extending from a lead frame boundary towards a central region of said lead frame;
encapsulating said lead frame with a first encapsulant such that a top surface of each of said leads is exposed from said first encapsulant;
mounting a semiconductor die on said first encapsulant located in said central region of said lead frame;
forming electrically conductive interconnects between die pads on said semiconductor die and said top surface of respective ones of said plurality of leads; and
encapsulating said semiconductor die, said conductive interconnects, and said top surface of said leads with a second encapsulant.

2. The method of claim 1 wherein said lead frame exhibits a first height, and said encapsulating said lead frame in said first encapsulant forms a molded structure having a second height that is approximately equivalent to said first height.

3. The method of claim 1 wherein said encapsulating said lead frame in said first encapsulant includes exposing a bottom surface of said leads from said first encapsulant.

4. The method of claim 1 wherein said encapsulating said lead frame in said first encapsulant is performed prior to said operations of mounting, forming, and encapsulating with said second encapsulant.

5. The method of claim 1 wherein said lead frame is a flagless lead frame, and said mounting operation includes directly coupling said semiconductor die to said first encapsulant in said central region.

6. The method of claim 1 wherein said semiconductor die has a connection pad surface with said die pads thereon and a second surface on an opposite side of said semiconductor die from said connection pad surface, and said mounting operation couples said second surface of said semiconductor die to said first encapsulant in said central region.

7. The method of claim 6 wherein said second surface of said semiconductor die is approximately coplanar with said top surface of said leads following said mounting operation.

8. The method of claim 1 further comprising separating said leads from said lead frame boundary following both of said encapsulating operations.

9. The method of claim 1 wherein said semiconductor die is sandwiched between said first encapsulant and said second encapsulant following both of said encapsulating operations.

10. A method for manufacturing a plurality of semiconductor packages comprising:
providing an electrically conductive sheet of flagless lead frames, each of said flagless lead frames having a plurality of leads extending from a lead frame boundary towards a central region of said lead frame;
encapsulating said electrically conductive sheet of flagless lead frames with a first encapsulant such that a top surface of each of said leads is exposed from said first encapsulant;
mounting semiconductor dies on said first encapsulant located in each said central region of said each of said flagless lead frames by directly coupling said semiconductor dies to said first encapsulant;
forming electrically conductive interconnects between die pads on said semiconductor dies and said top surface of respective ones of said plurality of leads;
encapsulating said semiconductor dies, said conductive interconnects, and said top surface of said leads with a second encapsulant to form a composite structure; and
separating said composite structure into said plurality of semiconductor packages following both of said encapsulating operations, each of said semiconductor dies being sandwiched between a portion of said first encapsulant and a portion of said second encapsulant.

11. The method of claim 10 wherein said electrically conductive sheet of flagless lead frames exhibits a first height, and said encapsulating said electrically conductive sheet in said first encapsulant forms a molded structure having a second height that is approximately equivalent to said first height.

12. The method of claim 10 wherein said encapsulating said electrically conductive sheet in said first encapsulant is performed prior to said operations of mounting, forming, and encapsulating with said second encapsulant.

13. The method of claim 10 wherein each of said semiconductor dies has a connection pad surface with said die pads thereon and a second surface on an opposite side of said semiconductor die from said connection pad surface, and said mounting operation couples said second surface of said semiconductor die directly to said first encapsulant in said central region.

14. The method of claim 13 wherein said second surface of said each of said semiconductor dies is approximately coplanar with said top surface of said leads following said mounting operation.

15. A semiconductor package comprising
a lead frame embedded in a first encapsulant, said lead frame being formed from an electrically conductive sheet having a plurality of leads extending from a lead frame boundary towards a central region of said lead frame, wherein a top surface of each of said leads is exposed from said first encapsulant;
a semiconductor die in direct contact with said first encapsulant located in said central region of said lead frame;
conductive interconnects electrically connected between die pads on said semiconductor die and said top surface of respective ones of said plurality of leads; and
a second encapsulant covering said semiconductor die, said conductive interconnects, and said top surface of said leads.

16. The semiconductor package of claim 15 wherein said lead frame exhibits a first height, and said lead frame embedded in said first encapsulant forms a molded structure having a second height that is approximately equivalent to said first height.

17. The semiconductor package of claim 15 wherein a bottom surface of said leads is exposed from said first encapsulant.

18. The semiconductor package of claim 15 wherein said semiconductor die has a connection pad surface with said die pads thereon and a second surface on an opposite side of said semiconductor die from said connection pad surface, said second surface of said semiconductor die being coupled to said first encapsulant in said central region.

19. The semiconductor package of claim 18 wherein said second surface of said semiconductor die is approximately coplanar with said top surface of said leads.

20. The method of claim 18 wherein said semiconductor die is sandwiched between said first encapsulant and said second encapsulant.
